(19) United States
(12) Patent Application Publication
(10) Pub. No.: US 2023/0260874 A1
(43) Pub. Date: Aug. 17, 2023

(54) MULTI-MODAL FLOW BALANCING FOR POWER SEMICONDUCTOR MODULE COOLING

(71) Applicants: George R. Woody, Clinton, AR (US); David L. Bogdanchik, Pasadena, CA (US); Alden C. McLean, Los Angeles, CA (US)

(72) Inventors: George R. Woody, Clinton, AR (US); David L. Bogdanchik, Pasadena, CA (US); Alden C. McLean, Los Angeles, CA (US)

(21) Appl. No.: 18/110,363

(22) Filed: Feb. 15, 2023

Related U.S. Application Data
(63) Continuation-in-part of application No. 17/672,681, filed on Feb. 15, 2022.

(51) Int. Cl. H01L 23/473

(52) U.S. Cl. CPC H01L 23/473

(57) ABSTRACT

A high performance, low-profile semiconductor heat dissipation apparatus that is able to achieve increased heat dissipation efficiency, greater heat dissipation uniformity, and greater heat dissipation control through the use of multiple modes of innovative coolant fluid flow balancing.

### CROSS-REFERENCE TO RELATED APPLICATIONS

This application is a Continuation-in-Part of U.S. Non-Provisional Utility patent application Ser. No. 17/672,681, titled: “THREE-DIMENSIONAL FLOW BALANCE FOR POWER MODULE COOLING,” filed Feb. 15, 2022, which is a Non-Provisional Utility Patent application claims the priority date of U.S. Provisional Application No. 63/149,585, titled: “THREE DIMENSIONAL FLOW BALANCE FOR POWER MODULE COOLING,” filed Feb. 15, 2021, the disclosures of both are hereby incorporated by reference in its entirety.

### FIELD OF THE PRESENT DISCLOSURE

This disclosure relates generally to power semiconductor heat dissipation technology and more specifically to an improved semiconductor heat dissipation apparatus utilizing an innovative multi-modal flow balancing technology to yield more uniform, controlled, and thermally efficient heat transfer.

### BACKGROUND OF THE RELATED ART

When designing power electronics, such as inverters, converters, chargers, etc . . . , heat dissipation is a critical issue. Excessive heat can lead to premature deterioration of both physical and electrical properties which, in turn, can cause both intermittent and permanent failures. Further, even when operating within acceptable temperature ranges, the ability to operate at cooler temperatures is almost always desirable because cooler operating temperatures typically provide increased electrical efficiency, greater long-term reliability, greater high-performance capability, and/or the ability to shrink the power electronic components into a smaller and/or more low-profile design footprint. In almost all highly competitive fields of electronic technology, the above aforementioned advantages are of critical importance so even marginal increases in heat dissipation efficiency can be of great importance.

To achieve greater heat dissipation capability, power semiconductor devices are often coupled with a heat sink of some variety which is in direct contact or thermal communication with a cooling fluid that is capable of drawing heat energy from a heat transfer surface and transporting the extracted heat energy away from device for ultimate dissipation.

One such device is described in U.S. Pat. No. 10,892,208 (“the '208 patent”). The '208 patent describes a heat dissipation device capable of achieving higher heat transfer efficiency than its contemporary designs by utilizing flow-balancers to initially manipulate the hydrodynamic pressure of cooling fluid so as to regulate the uniformity of flow of cooling fluid across the heat exchanging surface.

When the '208 legacy design is in a vertical orientation, cooling fluid enters the apparatus through an influent that leads to a first, upper plenum and then travels past a heat exchange surface until it reaches a second, lower plenum and finally exits the apparatus through an effluent. The significant innovation of the heat dissipation device disclosed in the '208 patent is the existence of “flow-balancers” located in either the first, upper plenum, or the second, lower plenum, or both, which are designed to alter the internal cross-sectional area of the plenum(s) within which the flow-balancers are located, which, in turn, alters the hydrostatic pressure and regulates the flow distribution of the cooling fluid across the heat transfer surface.

As disclosed in the '208 patent, such increased regulation of the coolant fluid flow distribution can yield significant improvements. Theoretical modeling via Computational Fluid Dynamics (CFD) conservatively suggest reductions in power semiconductor junction temperatures by as much as twenty-five percent (25%) are possible, and actual test results have achieved even more impressive results, including reductions by as much as thirty-three percent (33%).

While such use of single-mode flow balancing has demonstrated impressive results in both theory and in practice, there is still room for further improvement because the rate of heat transfer is not uniform in the direction of the coolant flow because as the cooling fluid flows across the heat transfer surface it absorbs heat and the temperature delta between the heat absorbing surface and the cooling fluid narrows thus reducing the effective rate of heat transfer creating non-uniform heat transfer across the length of the heat absorbing surface.

This natural degradation of thermal efficiency could be mitigated if the heat transfer coefficient of the cooling fluid could increase progressively as the temperature delta decreased which would occur if the flow rate progressively increased such that the cooling fluid transitioned from laminar to turbulent flow. Such transition is possible to induce if the cooling fluid is regulated using additional modes of flow balance as it progresses across the heat transfer surface. There exists a need for a heat dissipation apparatus capable of regulating cooling fluid flow using additional flow balance modalities.

The present disclosure distinguishes over the related art providing heretofore unknown advantages as described in the following summary.

### BRIEF SUMMARY OF THE INVENTION

The present disclosure describes a novel and innovative heat dissipation apparatus that is more thermally efficient than legacy designs, comprising at least one power semiconductor device in direct contact or in thermal communication with a heat sink, and a manifold capable of multi-modal coolant fluid flow balance across a heat sink. The primary innovative advantage of the multi-modal flow balancing is that it is capable of inducing a more efficient, uniform, and controlled heat transfer than legacy designs of similar size and profile.

The apparatus is intended for cooling a variety of semi-conductor dies such as, but not limited to, IGBTs, SI MOSFETs, SiC MOSFETs, JFETs, DIODES for use in power electronics such as inverters, converters, chargers, etc. The die of the power semi-conductor should be in direct contact or close thermal communication with the heat sink being cooled.

The opposing side of the heat sink may present a variety of features designed to promote heat dissipation such as micro fins or pin fins. Such features may be round, square, or some other shape designed to maximize surface area for contact with cooling fluid and encouraging heat transfer.

Coupled to the heat sink is a manifold designed to guide the flow of a cooling fluid within thermal communication with the heat sink to encourage the absorption and transport of heat energy for dissipation elsewhere. The manifold comprises an influent to guide cooling fluid ingress, a first and second plenum on opposing distal ends of at least one flow channel, and an effluent to facilitate cooling fluid egress.

Similar to legacy designs, either the first or second plenum, or both, may feature internal flow balancing features to manipulate hydrostatic pressure entering the flow channel to control the coolant flow rate through the flow channel, or such features can be used to balance flow between the multiple flow channels to achieve the desired division of coolant fluid through each respective flow channel. The balancing or regulation of flow is achieved by narrowing the plenum in strategic locations to increase hydrodynamic pressure where necessary to achieve the desired pressure gradient. This legacy method flow balancing can be used in conjunction with additional novel modes of flow balancing to further improve results.

The novelty of the presently disclosed apparatus is the additional thermal efficiency and heat transfer control achieved through utilizing additional novel modes of cooling fluid flow balancing.

In the presently disclosed apparatus, an additional innovative mode of flow balancing is utilized by manipulating the pressure gradient along the entire length of the flow channel(s) by progressively narrowing the flow channel's cross section. The effect of this progressive narrowing is to cause the cooling fluid flow rate to increase, which, if properly designed and calibrated, will cause the cooling fluid to progressively transition from laminar flow to turbulent flow during its passage through the flow channel.

Because cooling fluid in turbulent flow typically has a higher heat transfer coefficient, the progressive restriction of the flow channel's cross section yields a progressively increased coefficient of heat transfer which, in turn, serves to offset the natural degradation of thermal efficiency that occurs as a result of the rising temperature of the cooling fluid due to the absorbed heat energy.

Thus, if properly designed and calibrated, the presently disclosed heat transfer apparatus will gradually increase the heat transfer coefficient as the fluid loses its heat absorptive capacity creating a more uniform heat absorption capability along the entire length of the flow channel(s).

This additional innovative mode of flow balancing can also be utilized in an asymmetric or non-progressive manner when heat dissipation in a purposefully non-uniform manner is desired, such as when a module contains various power semiconductor devices that generate heat in an asymmetric manner.

A second additional innovative mode of flow balancing featured in the presently disclosed apparatus is the use of “gates” or “terminus restrictions” located at either the beginning terminus or end terminus of the flow channel(s), or at both. Gates can be used to temporarily increase flow speed of cooling fluid entering or exiting the flow channels thereby temporarily restricting the cross-sectional area of the flow channel and thereby increasing the turbulence of the cooling fluid. Such temporary restrictions can also be used to control cooling fluid flow turbulence and/or the relative distribution of cooling fluid between multiple flow channels. When properly designed and calibrated, gates or terminus restrictions can be utilized alone or in conjunction with other modes of flow balancing to achieve greater flow control to create either more uniform heat transfer experience or purposefully more asymmetric or non-uniform heat transfer performance.

While actual results will always vary depending on a myriad of specific real-world parameters, lab testing confirmed the disclosed improved performance of the innovative flow-balancing features by comparing the performance of a cooling manifold featuring the disclosed innovative flow-balancing technology (as depicted in FIG. 6) to a legacy manifold without such technology (as depicted in FIG. 8) while cooling an identical power semiconductor test array. The following is a summary of the performance data.

Legacy apparatus featuring manifold without innovative flow-balancing technology:
Presently disclosed innovative apparatus with flow-balancing technology:

As can easily be visually gleaned from the heat-proportionate shading of the test data, the presently disclosed innovative apparatus exhibited far more uniform results. The legacy apparatus exhibited both higher temperature hot spots and lower temperature cold spots.

The importance of the superior performance exhibited by the presently disclosed innovative apparatus cannot be overstated in high-performance applications that are continuously pushing the physical performance limits of a variety of power semiconductor devices.

This disclosure teaches certain benefits in construction and use which give rise to the objectives described below.

A primary objective inherent in the above-described apparatus is to provide advantages not taught by the prior art.

Another objective is to provide a power semiconductor heat dissipation apparatus with multiple modes of flow balancing to achieve increased heat dissipation efficiency.

A further objective is to provide a power semiconductor heat dissipation apparatus with multiple innovative modes of flow balancing to achieve greater heat dissipation uniformity.

A still further objective is to provide a power semiconductor with multiple innovative modes of flow balancing dissipation to achieve greater heat dissipation control.

Other features and advantages of the present invention will become apparent from the following more detailed description, taken in conjunction with the accompanying drawings, which illustrate, by way of example, the principles and features of the presently described apparatus.

### BRIEF DESCRIPTION OF THE SEVERAL VIEWS OF THE DRAWING(S)

The accompanying drawings illustrate various exemplary implementations and are part of the specification. The illustrated implementations are proffered for purposes of example, not for purposes of limitation. Illustrated elements will be designated by numbers.

Once designated, an element will be identified by the identical number throughout. Illustrated in the accompanying drawing(s) is at least one of the best mode embodiments of the present disclosure. In such drawing(s):

FIG. 1 is a perspective view of the presently disclosed heat dissipation apparatus capable of multi-modal flow-balancing for increased heat dissipation uniformity and control.

FIG. 2 is a cutaway perspective view of the presently disclosed heat dissipation apparatus illustrating a manifold featuring multiple flow channels that progressively narrow between the first and second plenum.

FIG. 3 is a cutaway plan view of the presently disclosed heat dissipation apparatus illustrating a manifold featuring at least one flow channel that progressively narrows between the first and second plenum.

FIG. 4 is a perspective view of the presently disclosed heat dissipation apparatus shown unencapsulated thereby exposing an array of the power semiconductor devices affixed to a heat sink which is coupled with the flow-balancing cooling manifold.

FIG. 5 is a cutaway plan view of an unencapsulated embodiment of the presently disclosed heat dissipation apparatus illustrating a manifold featuring a more gradual progressively narrowing flow channel between a first and second plenum.

FIG. 6 is a perspective view of an exemplar manifold of presently disclosed heat dissipation apparatus illustrating multiple innovative features designed to utilize different modes of coolant fluid flow balance.

FIG. 7 is a perspective view of another embodiment of a manifold of the presently disclosed heat dissipation apparatus illustrating multiple innovation features designed to promote more uniform, controlled, and thermally efficient heat transfer through flow balancing.

FIG. 8 is a perspective view of an exemplar legacy manifold without any of the presently disclosed innovative flow balance features. A similar manifold was used to generate the legacy performance data that was compared against the data generated by the presently disclosed novel apparatus to confirm the claimed superior performance.

### DETAILED DESCRIPTION OF THE EXEMPLARY EMBODIMENT

The above-described drawing figures illustrate an exemplary embodiment of presently disclosed apparatus and its many features in at least one of its preferred, best mode embodiments, which is further defined in detail in the following description. Those having ordinary skill in the art may be able to make alterations and modifications to what is described herein without departing from its spirit and scope of the disclosure. Therefore, it must be understood that what is illustrated is set forth only for the purposes of example and that it should not be taken as a limitation in the scope of the present apparatus or its many features.

Described now in detail are a series of drawings depicting various features and details for the purpose of further clarifying the presently disclosed apparatus and method.

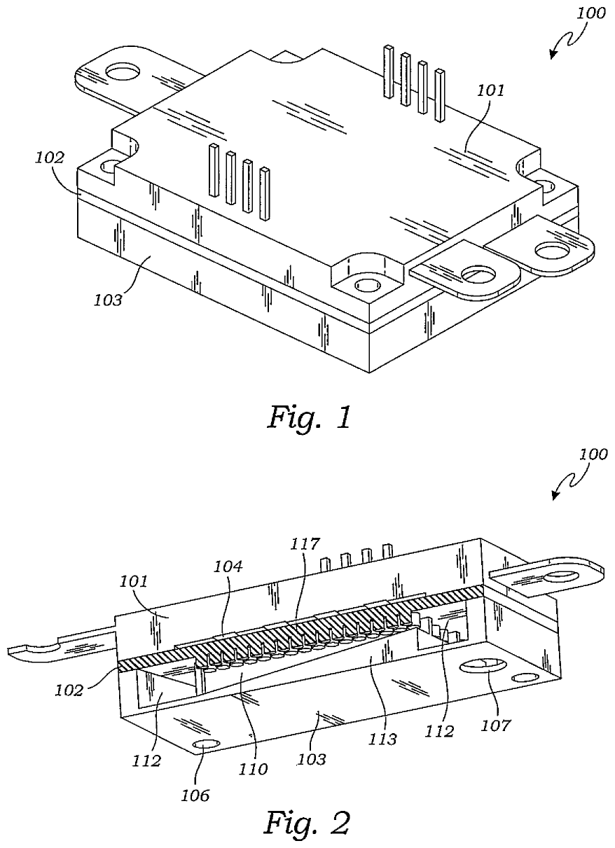

FIG. 1 is a perspective view of an exemplar embodiment of the presently disclosed innovative heat dissipation apparatus 100. The apparatus 100 is illustrated in FIG. 1 with the power semiconductor devices covered by a transfer molded or encapsulation layer 101 leaving only the eight depicted power and/or signal leads visible. The innovative device 100 also features a heat sink 102 and a coolant fluid manifold 103 which is capable of balancing coolant fluid flow to yield more efficient and uniform heat transfer from the heat sink 102 and/or more purposefully asymmetric or non-uniformed heat transfer from the heat sink 102.

FIG. 2 illustrates a cutaway perspective view of an exemplar embodiment of the presently disclosed apparatus 100. In the depicted embodiment 100, the influent 106, for cooling fluid ingress, and the effluent 107, for cooling fluid egress, are located on the bottom of the apparatus 100 in its presently depicted orientation. The cutaway in FIG. 2 exposes the heat dissipation fins or pins 117 of the heat sink 102, the flow channels 110, and a first and second plenum 112 located on each opposing terminal ends of said flow channels 110. Most importantly, FIG. 2 illustrates the second mode of flow balancing which is the progressive reduction of the flow channels' 110 cross sectional area along the entire length of each flow channel 110. In the orientation depicted in FIG. 2, the reduction is achieved by raising the lower surface 113 of each flow channel 110 progressively in a ramp-like fashion, thereby decreasing the distance between the heat dissipation pins 117 and the lower surface 113 of each flow channel 110. This reduction in the flow channels' cross-sectional area will cause the cooling fluid to flow faster and more turbulently across the heat sink's 102 pins or fins 117, which, if calibrated correctly, will mitigate the natural degradation of the cooling fluid's capacity to absorb heat energy from the heat sink 102 as the cooling fluid continues to absorb more heat energy.

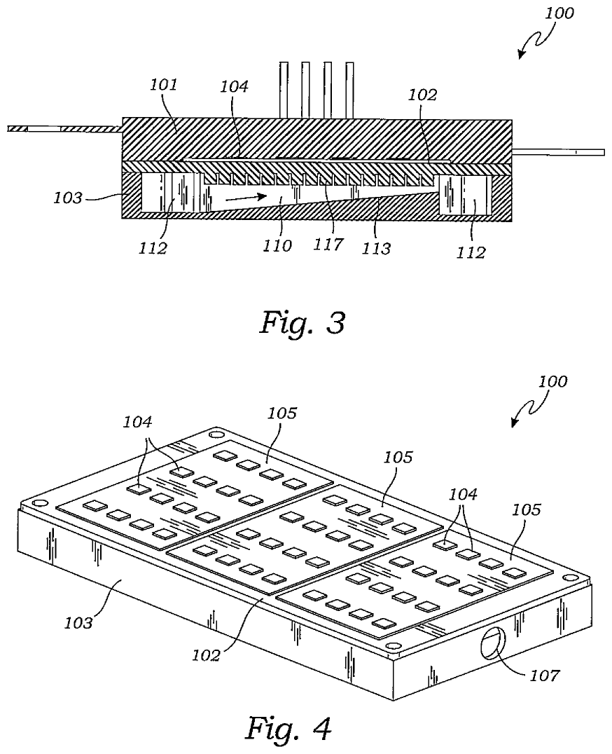

FIG. 3 is a cutaway plan view of an embodiment of the presently disclosed apparatus 100 showing the profile of a series of power semiconductors 104 protected by a transfer molded or encapsulation layer 101 above and in thermal communication with a heat sink 102 below. The heat sink 102 features a plurality of pins or fins 117 which comprise the upper surface of at least one flow channel(s) 110 through which cooling fluid can flow between a first and second plenum 112. The perspective illustrated in FIG. 3 also depicts the innovative feature designed to induce the second disclosed mode of flow balancing, namely, the progressive reduction of the flow channels' 110 cross-sectional area by raising the lower surface 113 of the flow channel(s) 110 in a ramp-like fashion causing the cooling fluid flow to progressively increase in speed and turbulence, which, in turn, will increase the cooling fluid's coefficient of heat transfer as it advances along the flow channel 110. If the apparatus 100 is calibrated correctly, the cooling fluid will transition from a state of more laminar flow with a lower heat transfer coefficient to a state of more turbulent flow with a higher heat transfer coefficient, progressively, during its passage through the flow channel(s) 110.

FIG. 4 is a perspective view of the presently disclosed apparatus 100 depicted without a transfer molded or encapsulation layer 101 shown in FIG. 3 thereby illustrating an exposed array of power semiconductor devices 104 uniformly mounted on three separate direct bonded copper plates (DBC's) 105 which are affixed to a heat sink 102, which is, in turn, coupled to a cooling manifold 103. The cooling manifold 103 features an influent for cooling fluid ingress and an effluent 107 for cooling fluid egress; however, from the perspective illustrated in FIG. 4, only the effluent 107 is visible. Typically, when a design requires an array of uniformly mounted semiconductor devices 104, as depicted in FIG. 4, the goal is to achieve uniform cooling so that each device experiences a similar thermal environment. This is important because if devices 104 mounted closer to the cooling manifold 103 effluent 107 are routinely exposed to higher operating temperatures, such devices could exhibit poorer performance and/or shorter operating lifespans. The issue is addressed by the presently disclosed novel apparatus 100 because the innovative multi-modal flow balancing technology can increase the uniformity of heat transfer that can be achieved in such designs.

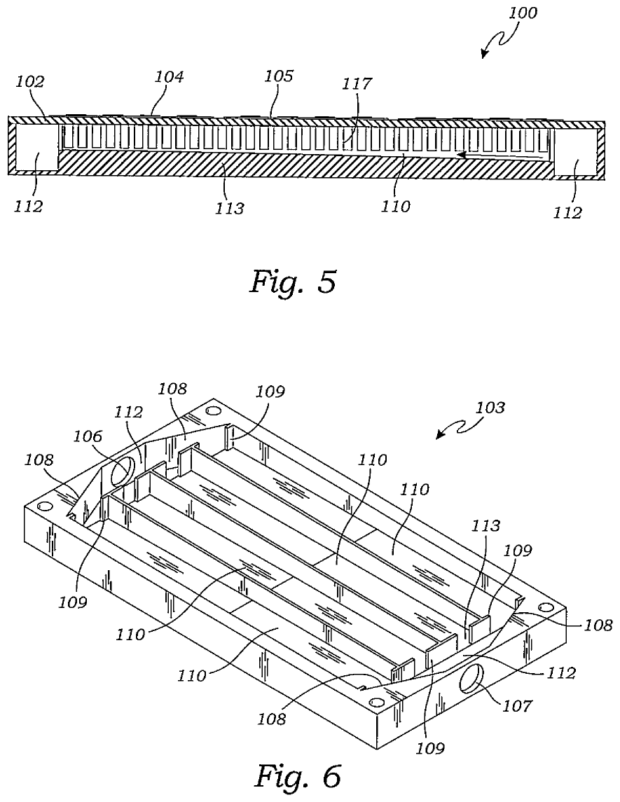

FIG. 5 illustrates a cutaway plan view of the unencapsulated embodiment of the presently disclosed apparatus 100 illustrated in FIG. 4. FIG. 5 illustrates a profile of the several power semiconductor devices 104 mounted on DBC's 105 which are in direct physical contact and thermal communication with a heat sink 102 featuring a plurality of pins and/or fins 117 running the length of at least one flow channel 110. Other embodiments might feature pins and/or fins of other shapes or designs so long as the system is designed to transfer the heat at a sufficient rate. Similar to previous figures, FIG. 5 also depicts a progressively narrowing flow channel 110 running between a first and second plenum 112. As in the other figures, the flow channel in FIG. 5 progressively narrows because lower surface 113 of the flow channel progressively raises along the length of the flow channel 110. Other embodiments of the presently disclosed apparatus 100 might alter other dimensions of the flow channel 110 to achieve the desired progressive cross-sectional narrowing.

FIG. 6 is a perspective view of an exemplar embodiment of a cooling manifold 103 of the presently disclosed apparatus 100 illustrating multiple features designed to induce different modes of flow balancing. This exemplar cooling manifold 103 illustrates a centrally oriented influent 106 for coolant fluid to enter a first plenum 112 which then flows through a plurality of flow channels 110 to a second plenum 112 and eventually egresses through a centrally located effluent 107. A first mode of flow balancing via the angled walls 108 of both the first and second plenums 112 allows the cooling fluid to be intentionally apportioned between the several flow channels 110 through hydrostatic pressure gradients established by such angled walls 108 in both plenums 112.

A second mode of flow balancing, perhaps less obvious from this illustration, is the progressively decreased cross-sectional area of the flow channels 110 along the length of the flow channels 110 between the first and second plenums 112. In the embodiment illustrated FIG. 6, this is achieved by progressively raising the lower surface 113 of the flow channel 110. As previously stated, other embodiments may achieve a progressively narrowing flow channel 110 cross section by manipulating other flow channel 110 dimensions.

A third mode of novel flow balancing utilized by the exemplar coolant manifold 103 illustrated in FIG. 6 is induced by the use of flow channel terminus restrictions called “gates” 109. As depicted in FIG. 6, gates 109 are temporary reductions to the cross-sectional area of the flow channels 110 located at either end or terminus of the flow channel(s) 110 that do not persist or extend along the flow channel 110 for any appreciable length. Gates 109 serve two different flow balancing functions. First, gates 109 serve to restrict initial coolant flow into the flow channels 110 creating or contributing to a hydrodynamic pressure gradient in the plenums 112. This can assist in the apportionment of coolant fluid between multiple flow channels 110. Second, gates 109 temporarily and abruptly increase the flow rate of the cooling fluid, which thereby temporarily and abruptly increase the cooling fluid's level of turbulence and its coefficient of heat transfer. Together gates 109 can be used in conjunction with one or more other novel flow balancing features depicted in FIG. 6 to create a more uniform, controlled, and thermally efficient heat transfer experience than legacy devices.

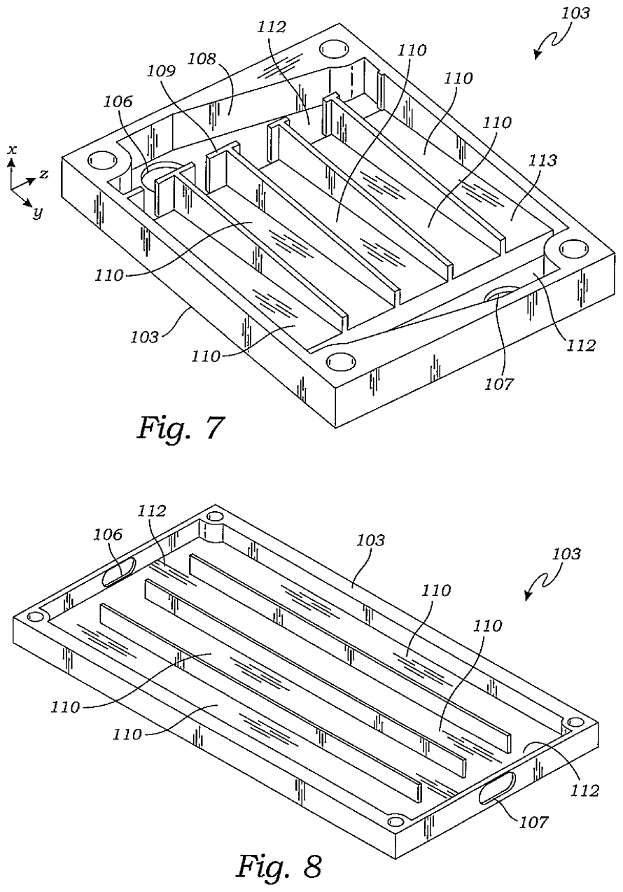

FIG. 7 illustrates a perspective view of the cooling manifold 103 of a different embodiment of the presently disclosed apparatus 100. In the embodiment illustrated in FIG. 7, the influent 106 and effluent 107 are located on the bottom of the cooling manifold and closer to one side. In such manifold 103 embodiments, the angled walls 108 of the plenums 112 and the gates 109 located at the beginning terminus of the flow channels 110 serve to manipulate the hydrodynamic pressure in the first plenum 112 to assure equal coolant flow reaches each flow channel 110. Similar to previously illustrated embodiments, FIG. 7 also features a plurality of parallel flow channels 110 that are progressively narrowed using a rising ramp-like lower surface 113. Multiple alternative embodiments are possible, and with the use of one or more novel modes of flow balancing to control coolant flow, greater heat transfer uniformity and thermally efficiency can be achieved.

FIG. 8 illustrates a typical legacy coolant manifold 103 without any of the presently disclosed innovative flow balancing features. The legacy manifold 103 illustrated in FIG. 8 features a centrally located influent 106 allowing ingress of cooling fluid to a first plenum 112, a plurality of parallel flow channels 110 connecting a first and second plenum 112, and second plenum 112 with a centrally located effluent 107 allowing egress of cooling fluid. The legacy manifold 103 contains no angled walls (108 in previous figures) in the plenums 112 to manipulate hydrodynamic force, no gates (109 in previous figures) at the flow channel 110 terminuses, and no mechanism to progressively narrow the flow channels 110 (such as 113 in previous figures). As a result of the lack of all the presently disclosed innovative flow balancing features, the manifold 103 illustrated in FIG. 8 has no means of increasing heat transfer uniformity and efficiency and cannot perform at the same level as the presently disclosed innovative apparatus 100. This was confirmed by the test data included in paragraph twenty-two (22) which was generated by comparing the performance of a legacy maniform similar to the one illustrated in FIG. 8 to a novel high-performance manifold 103 similar to the one illustrated in FIG. 6.

The enablements described in detail above are considered novel over the prior art of record and are considered critical to the operation of at least one aspect of the apparatus and its method of use, and to the achievement of the above-described objectives. The words used in this specification to describe the instant embodiments are to be understood not only in the sense of their commonly defined meanings, but to include by special definition in this specification: structure, material, or acts beyond the scope of the commonly defined meanings. Thus, if an element can be understood in the context of this specification as including more than one meaning, then its use must be understood as being generic to all possible meanings supported by the specification and by the word(s) describing the element.

The definitions of the words or drawing elements described herein are meant to include not only the combination of elements which are literally set forth, but all equivalent structures, materials or acts for performing substantially the same function in substantially the same way to obtain substantially the same result. In this sense it is therefore contemplated that an equivalent substitution of two or more elements may be made for any one of the elements described and its various embodiments or that a single element may be substituted for two or more elements in a claim.

Changes from the claimed subject matter as viewed by a person with ordinary skill in the art, now known or later devised, are expressly contemplated as being equivalents within the scope intended and its various embodiments. Therefore, substitutions, now or later known to one with ordinary skill in the art, are defined to be within the scope of the defined elements. This disclosure is thus meant to be understood to include what is specifically illustrated and described above, what is conceptually equivalent, what can be obviously substituted, and also what incorporates the essential ideas.

The scope of this description is to be interpreted only in conjunction with the appended claims and it is made clear, here, that each named inventor believes that the claimed subject matter is what is intended to be patented.

What is claimed:

1. An improved power semiconductor heat dissipation apparatus, said apparatus comprising:
a liquid heat exchange manifold featuring:
an influent through which coolant fluid may flow into said manifold;
an effluent through which coolant fluid may flow out of said manifold;
a first and second plenum separated by at least one flow channel extending between said first plenum and said second plenum,
said first plenum defined by the space within the manifold between the influent and the said at least one flow channels and said second plenum defined by the space within the manifold between said at least one flow channel and said effluent;
a heat sink positioned to be in thermal communication with the cooling fluid in said at least one flow channel;
at least one power semiconductor device mounted in thermal communication with said heat sink;
wherein at least one plenum, between said first plenum and said second plenum, is shaped to create a hydrodynamic pressure gradient across a dimension of said plenum;
wherein the cross-sectional area of said at least one said flow channel is progressively reduced along the length of said flow channel to create a hydrodynamic pressure gradient along the length of said at least one flow channel.

2. An apparatus as in claim 1 further comprising a reduced cross-sectional area at the beginning and/or end terminus of at least one flow channel, said reduced cross-sectional area not persisting along the length of said at least one flow channel in order to create a point of increased hydrodynamic pressure at said terminus of said at least one flow channel;

3. An improved power semiconductor heat dissipation apparatus, said apparatus comprising:
a liquid heat exchange manifold featuring:
an influent through which coolant fluid may flow into said manifold;
an effluent through which coolant fluid may flow out of said manifold;
a first and second plenum separated by at least one flow channel extending between said first plenum and said second plenum,
said first plenum defined by the space within the manifold between the influent and the said at least one flow channels and said second plenum defined by the space within the manifold between said at least one flow channel and said effluent;
a heat sink positioned to be in thermal communication with the cooling fluid in said at least one flow channel;
at least one power semiconductor device mounted in thermal communication with said heat sink;
wherein at least one plenum, between said first plenum and said second plenum, is shaped to create a hydrodynamic pressure gradient across a dimension of said plenum;
wherein the said at least one flow channel has a reduced cross-sectional area at the beginning and/or end terminus of at least one flow channel, said reduced cross-sectional area not persisting along the length of said at least one flow channel in order to create a point of increased hydrodynamic pressure at said terminus of said at least one flow channel.

4. An improved power semiconductor heat dissipation apparatus, said apparatus comprising:
a liquid heat exchange manifold featuring:
an influent through which coolant fluid may flow into said manifold;
an effluent through which coolant fluid may flow out of said manifold;
a first and second plenum separated by at least one flow channel extending between said first plenum and said second plenum,
said first plenum defined by the space within the manifold between the influent and the said at least one flow channels and said second plenum defined by the space within the manifold between said at least one flow channel and said effluent;
a heat sink positioned to be in thermal communication with the cooling fluid in said at least one flow channel;
at least one power semiconductor device mounted in thermal communication with said heat sink;
wherein the cross-sectional area of said at least one said flow channel is progressively reduced along the length of said flow channel to create a hydrodynamic pressure gradient along the length of said at least one flow channel;
wherein the said at least one flow channel has a reduced cross-sectional area at the beginning and/or end terminus of at least one flow channel, said reduced cross-sectional area not persisting along the length of said at least one flow channel in order to create a point of increased hydrodynamic pressure at said terminus of said at least one flow channel.

5. An improved power semiconductor heat dissipation apparatus, said apparatus comprising:
a liquid heat exchange manifold featuring:
an influent through which coolant fluid may flow into said manifold;
an effluent through which coolant fluid may flow out of said manifold;
a first and second plenum separated by at least one flow channel extending between said first plenum and said second plenum,
said first plenum defined by the space within the manifold between the influent and the said at least one flow channels and said second plenum defined by the space within the manifold between said at least one flow channel and said effluent;
a heat sink positioned to be in thermal communication with the cooling fluid in said at least one flow channel;
at least one power semiconductor device mounted in thermal communication with said heat sink;
wherein the cross-sectional area of said at least one said flow channel is progressively reduced along the length of said flow channel to create a hydrodynamic pressure gradient along the length of said at least one flow channel.

6. An improved power semiconductor heat dissipation apparatus, said apparatus comprising:
a liquid heat exchange manifold featuring:
an influent through which coolant fluid may flow into said manifold;
an effluent through which coolant fluid may flow out of said manifold;
a first and second plenum separated by at least one flow channel extending between said first plenum and said second plenum,
said first plenum defined by the space within the manifold between the influent and the said at least one flow channels and said second plenum defined by the space within the manifold between said at least one flow channel and said effluent;
a heat sink positioned to be in thermal communication with the cooling fluid in said at least one flow channel;
at least one power semiconductor device mounted in thermal communication with said heat sink;
wherein the said at least one flow channel has a reduced cross-sectional area at the beginning and/or end terminus of at least one flow channel, said reduced cross-sectional area not persisting along the length of said at least one flow channel in order to create a point of increased hydrodynamic pressure at said terminus of said at least one flow channel.
